(19) United States
(12) Patent Application Publication
(10) Pub. No.: US 2026/0050033 A1
(43) Pub. Date: Feb. 19, 2026

(54) Testing a Comparator Circuit

(71) Applicant: Google LLC, Mountain View, CA (US)

(72) Inventors: Wilson Pradeep, Fremont, CA (US); Tathagata Biswas, Bangalore (IN)

(73) Assignee: Google LLC, Mountain View, CA (US)

(21) Appl. No.: 18/806,589

(22) Filed: Aug. 15, 2024

(51) Int. Cl. G01R 31/317

(52) U.S. Cl. CPC G01R 31/31703; G01R 31/31727

(57) ABSTRACT

Techniques and apparatuses are described for testing a comparator circuit. In example aspects, a test point circuit can provide controllability and observability of signals and faults in a comparator circuit. The test point circuit uses a custom NOR-based design with an inverted input. With this custom design, the test point circuit can test for faults that other designs are unable to support. Example faults include stuck-at-one faults at an input of the comparator circuit or on a clock-enable signal. The use of the test point circuit improves test coverage and reduces test pattern count, which reduces the time and cost of testing a comparator circuit. In certain aspects, a storage circuit can be reused to implement the test point circuit, which enables testing of a comparator circuit to be implemented within space-constrained devices.

### BACKGROUND

Testing is an important factor in the design, development, and manufacturing of electronic devices. Detecting faults earlier can save time and money in addition to ensuring an electronic device works as intended. Some types of circuits within an electronic device can be particularly challenging to test. Controlling signals and observing faults associated with a comparator circuit, for instance, can be difficult as next-state outputs can be driven by complex logic that is difficult to control. In the absence of a mechanism that facilitates testing of comparator circuits, portions of the electronic device may go untested, which can lead to a significant loss of test coverage and increase the risk of a higher quantity of defective devices.

### SUMMARY

Techniques and apparatuses are described for testing a comparator circuit. In example aspects, a test point circuit can provide controllability and observability of signals and faults in a comparator circuit. The test point circuit uses a custom NOR-based design with an inverted input. With this custom design, the test point circuit can test for faults that other designs are unable to support. Example faults include stuck-at-one faults at an input of the comparator circuit or on a clock-enable signal. The use of the test point circuit improves test coverage and reduces test pattern count, which reduces the time and cost of testing a comparator circuit. In certain aspects, a storage circuit can be reused to implement the test point circuit, which enables testing of a comparator circuit to be implemented within space-constrained devices. The comparator circuit can be implemented as part of XOR-gating logic (e.g., self-gating logic), which can improve power efficiency by gating a clock signal at times when the clock signal is not necessary. Reuse of the storage circuit also allows the XOR-gating logic to be implemented at any stage of circuit synthesis.

Aspects described below include an apparatus comprising a comparator circuit and a test point circuit. The comparator circuit includes an XOR gate. The comparator circuit is configured to generate a comparator output signal at an output of the comparator circuit via the XOR gate. The test point circuit is configured to accept the comparator output signal at a first input of the test point circuit. The test point circuit is also configured to invert the comparator output signal to generate an inverted first input. The test point circuit is additionally configured to accept a test signal at a second input of the test point circuit. The test point circuit is further configured to perform an OR operation based on the inverted first input and the test signal to generate an intermediate signal. The test point circuit is also configured to invert the intermediate signal to generate a test point output signal.

Aspects described below also include a method for testing a comparator circuit. The method includes accepting a comparator output signal provided by an XOR gate. The method also includes inverting the comparator output signal to generate an inverted first input. The method additionally includes accepting a test signal. The method further includes performing an OR operation based on the inverted first input and the test signal to generate an intermediate signal. The method also includes inverting the intermediate signal to generate a test point output signal.

Aspects described below further include a system with means for testing a comparator circuit.

### BRIEF DESCRIPTION OF DRAWINGS

Apparatuses for and techniques for testing a comparator circuit are described with reference to the following drawings. The same numbers are used throughout the drawings to reference like features and components:

FIG. 1 illustrates an example environment in which testing of a comparator circuit can be implemented;

FIG. 2 illustrates an example device with a test point circuit capable of testing a comparator circuit;

FIG. 3 illustrates an example truth table for signals of a test point circuit;

FIG. 4 illustrates an example test point circuit for observing a comparator output signal;

FIG. 5 illustrates an example relationship between a test point circuit and other components of a device;

FIG. 6 illustrates an example implementation of a device with a test point circuit capable of testing multiple comparator circuits;

FIG. 7 is an example illustration of a third device including a test point circuit that facilitates testing of a comparator circuit;

FIG. 8 illustrates an example computing device capable of testing a comparator circuit; and

FIG. 9 depicts an example method for testing a comparator circuit.

### DETAILED DESCRIPTION

Power consumption by electronic devices is an increasingly important factor.

Environmental concerns motivate efforts to reduce the power consumed by electronic devices to help conserve the earth's resources. Less power consumption also translates to longer portable device operation between charges, smaller batteries for easier device portability, lower energy bills, and cooler device operation.

Some devices include circuits whose operations are controlled by a clock signal. Due to the complexities involved with generating the clock signal, it is not feasible to turn the clock signal off during times in which these circuits do not need to operate. To improve power efficiency, the electronic device can employ techniques to gate the clock signal (e.g., halt passing of the clock signal to the circuit) at times when the clock signal is not necessary. This effectively prevents the circuits from operating and consuming power, which reduces overall power consumption of the device.

Consider an example involving a register. To reduce dynamic power, the clock signal to the register is gated during clock cycles when data in the register remains unchanged. In particular, a comparator circuit uses an XOR gate to compare data stored in the register with data arriving at a data pin of the register. If the data is the same, the comparator circuit gates the clock signal to reduce the dynamic power.

Although use of the comparator circuit gate can assist with reducing power consumption, it presents another challenge in testing. Controlling signals and observing faults associated with an XOR gate, for instance, can be difficult as next-state outputs can be driven by complex logic that is difficult to control. In the absence of a mechanism that facilitates testing of XOR gates, portions of the electronic device may go untested, which can lead to a significant loss of test coverage and increase the risk of a higher quantity of defective devices.

Consider an example device having multiple XOR gates capable of gating multiple registers. To test a stuck-at-one fault at one register output, the input and output of the register must be set to zero for controllability and the outputs for the other registers must be set to zero for observability. In this case, a stuck-at-one fault at a point that controls the gating of the clock signal should have a value of one. However, none of the registers have unequal inputs and outputs in both the good and faulty simulation. Consequently, the fault cannot be observed. For similar reasons, a stuck-at-one fault on a clock input of the registers. This leads to significant test coverage loss and increases the risk of sending defective electronic devices to customers.

Some techniques address this issue by using a circuit to temporarily break the dependency between the input and output of the registers and by overriding a scan-enable input at the register. Unfortunately, this creates excessive timing closure overhead because the shift path needs to be timed with respect to the functional clock, which is challenging to meet due to the non-correlation of the functional path and the scan-shift path. This also adds an excessive overhead of an additional custom test mode where the scan-enable input is constrained to a value of one. The overhead is increased due to the extra necessary customization of an on-chip controller to capture extra clock cycles.

Other techniques insert a test point at the outputs of the XOR gates to control enabling and/or disabling of the clock signal. This can enable direct testing of the clock gate enable signal. It can also enable the capture and testing of next-state values independent of XOR-gating logic (e.g., self-gating logic). However, a clock enable stuck-at-one fault still cannot be tested. Also, the test point requires equal input and output values on the registers, which limits the stuck-at-one-fault effect observability. Furthermore, such a test point adds overhead of an additional register, an AND gate, and an OR gate per clock gate.

Another problem can exist when implementing XOR gating. In some techniques, both synthesis and physical implementation are performed in a single flow. Design for testing insertion steps, such as scan chain stitching and connection to test compression happens after initial logical operation. However, XOR gating only happens during the final compile stage. This prevents the addition of test point registers that would otherwise improve testability of the XOR-gating logic. The corresponding registers also have to be added during the design-for-testing insertion step to have them scan stitched. Unfortunately, pre-estimation of the number of required test points is infeasible at this stage and rough estimation results in inaccuracies and inefficiency. Furthermore, inserting test points through the native flow does not support a sharing option with registers, which limits area optimization.

To address these challenges, techniques are described for testing a comparator circuit. In example aspects, a test point circuit can provide controllability and observability of signals and faults in a comparator circuit. The test point circuit uses a custom NOR-based design with an inverted input. With this custom design, the test point circuit can test for faults that other designs are unable to support. Example faults include stuck-at-one faults at an input of the comparator circuit or on a clock-enable signal. The use of the test point circuit improves test coverage and reduces test pattern count, which reduces the time and cost of testing a comparator circuit. In certain aspects, a storage circuit (e.g., a register or a flip-flop) can be reused to implement the test point circuit, which enables testing of a comparator circuit to be implemented within space-constrained devices. The comparator circuit can be implemented as part of XOR-gating logic, which can improve power efficiency by gating a clock signal at times when the clock signal is not necessary. Reuse of the storage circuit also allows the XOR-gating logic to be implemented at any stage of circuit synthesis.

The test point circuit can provide a significant increase in test coverage compared to scan-enable override methods and other test points for testing comparator logic. Such comparator logic can include XOR-based comparator designs, bitwise XOR trees, and other comparator logic, regardless of whether XOR-gating is used. Example implementations can also provide a significant reduction in the overall pattern count, such as the number of test vectors to test a particular design, compared to prior test designs, which reduces test time and cost. The reuse of the storage circuit as a test point also brings the area overhead drastically down compared to other test points.

### Operating Environment

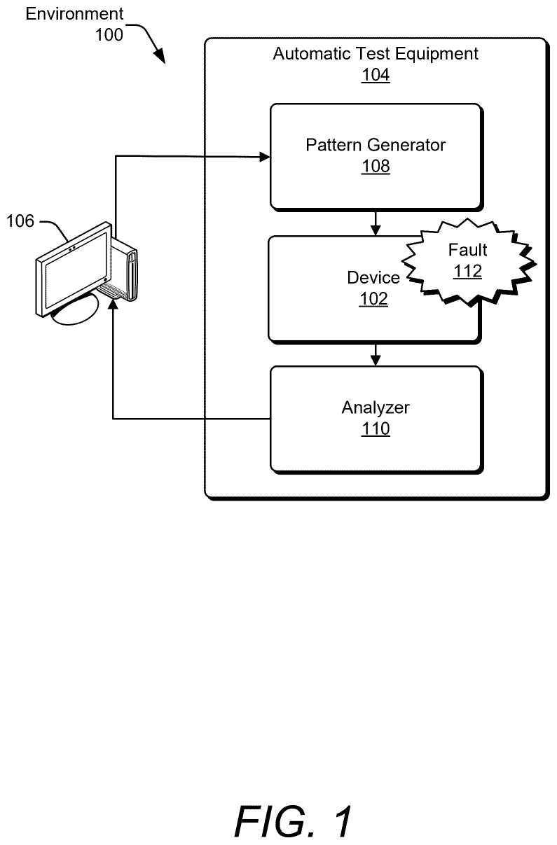

FIG. 1 is an illustration of an example environment 100 in which testing of a comparator circuit can be performed. The environment 100 includes a device 102 that is being tested by automatic test equipment 104. The device 102 can include integrated circuits, registers, flip-flops, scan cells, devices with complex logic, comparator circuits, storage circuits, digital signal processors, memory elements, and other devices and circuits.

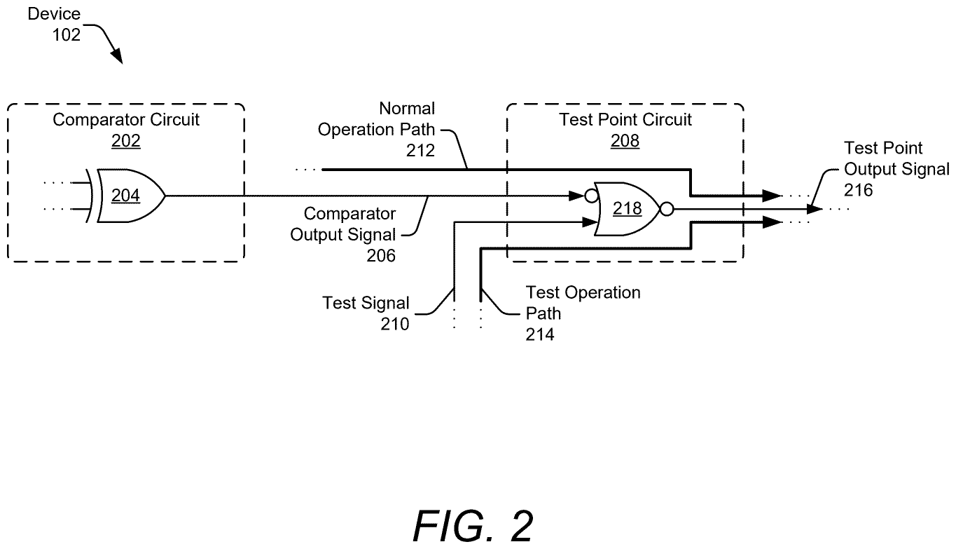

During operation, a computing device 106 can perform scan-based testing using a pattern generator 108 and an analyzer 110 of the automatic test equipment 104 to test the functionality of the device 102. For example, the computing device 106 can put the device 102 into a scan mode. The pattern generator 108 can perform automatic test pattern generation to create test patterns based on fault models that predict the expected behavior of the device 102 when faults are present. The pattern generator 108 can deliver the resulting test pattern data into the device 102. The computing device 106 can then briefly enable a functional mode of the device 102 to capture the test response. The computing device 106 can put the device 102 back into test mode to shift out the response. The analyzer 110 can compare the captured response to expected response data stored in the computing device 106. Any mismatches between the captured response and the expected response indicate a potential fault 112 in the device 102, which the computing device 106 can log for future evaluation. The device 102 is further described with respect to FIG. 2.

### Testing a Comparator Circuit

FIG. 2 illustrates an example of the device 102, which can perform testing of a comparator circuit. The device 102 includes a comparator circuit 202 that includes at least one XOR gate 204. The comparator circuit 202 can also include comparator logic, XOR-based comparator circuitry, bitwise XOR trees, and other comparator circuits. For example, the comparator circuit 202 can include an XOR tree that can be used for different applications, such as XOR gating, address comparison in a memory comparison circuit, other applications, or some combination thereof. The comparator circuit 202 can further include other elements, such as logic gates, storage circuits, or combinations thereof.

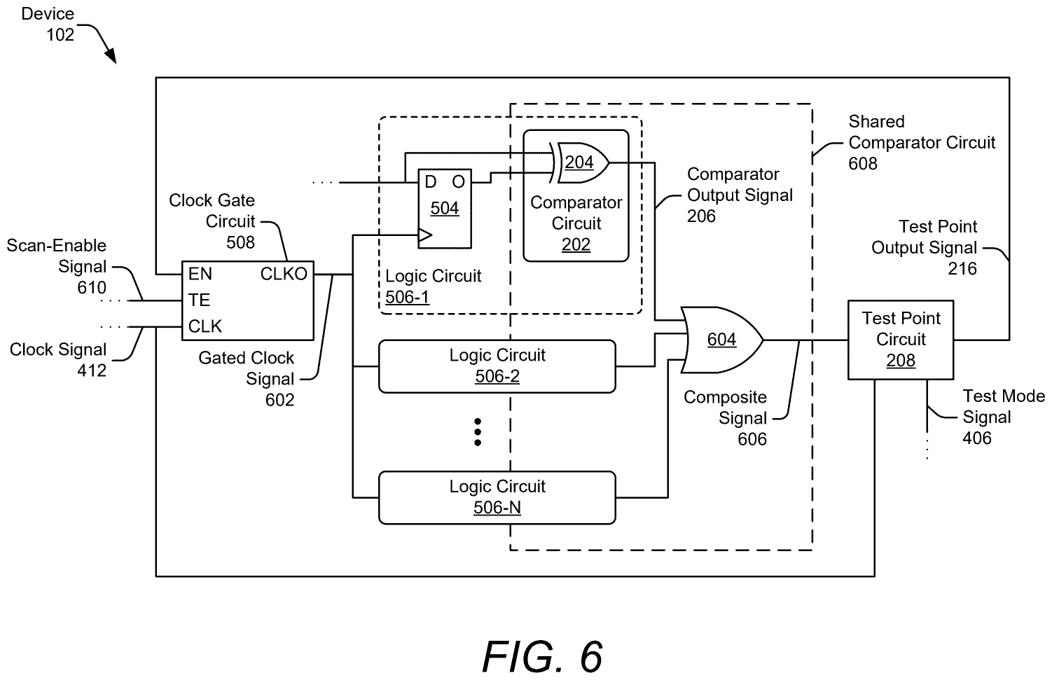

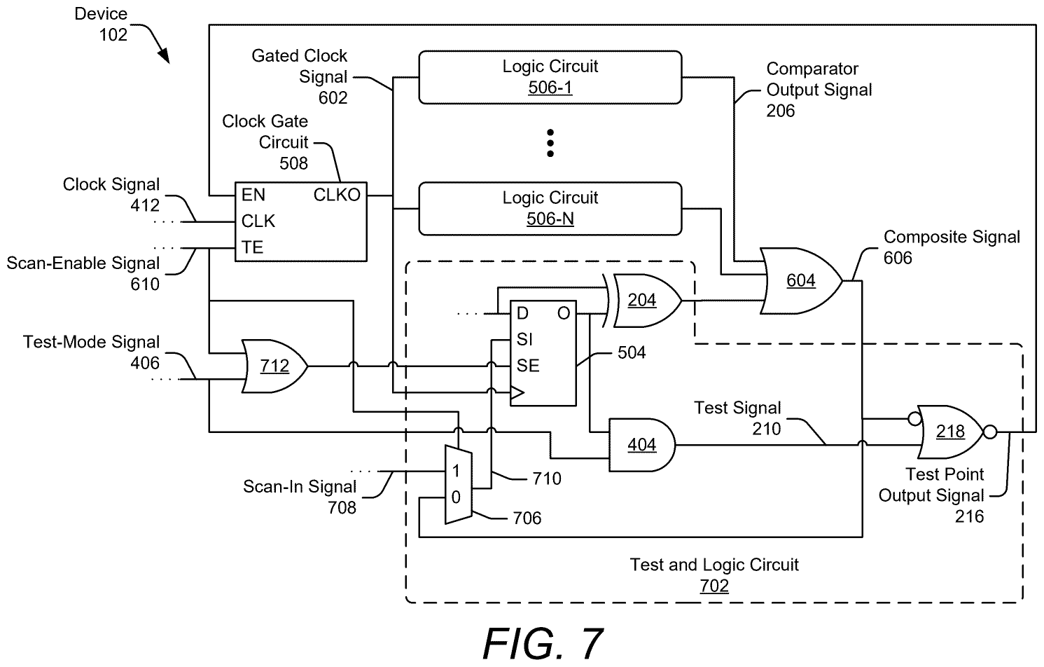

The comparator circuit 202 can generate a comparator output signal 206 via the XOR gate 204. In an example implementation, the comparator output signal 206 represents a direct output of the XOR gate 204, as shown in FIG. 2. Other implementations are also possible in which the comparator output signal 206 represents an output of the XOR gate 204 that can be further modified by other components of the comparator circuit 202. For instance, the comparator output signal 206 can represent an output of the XOR gate 204 that is further operated on by an OR gate of the comparator circuit 202, as shown in FIGS. 6 and 7. In general, the comparator output signal 206 is generated, at least in part, using the XOR gate 204.

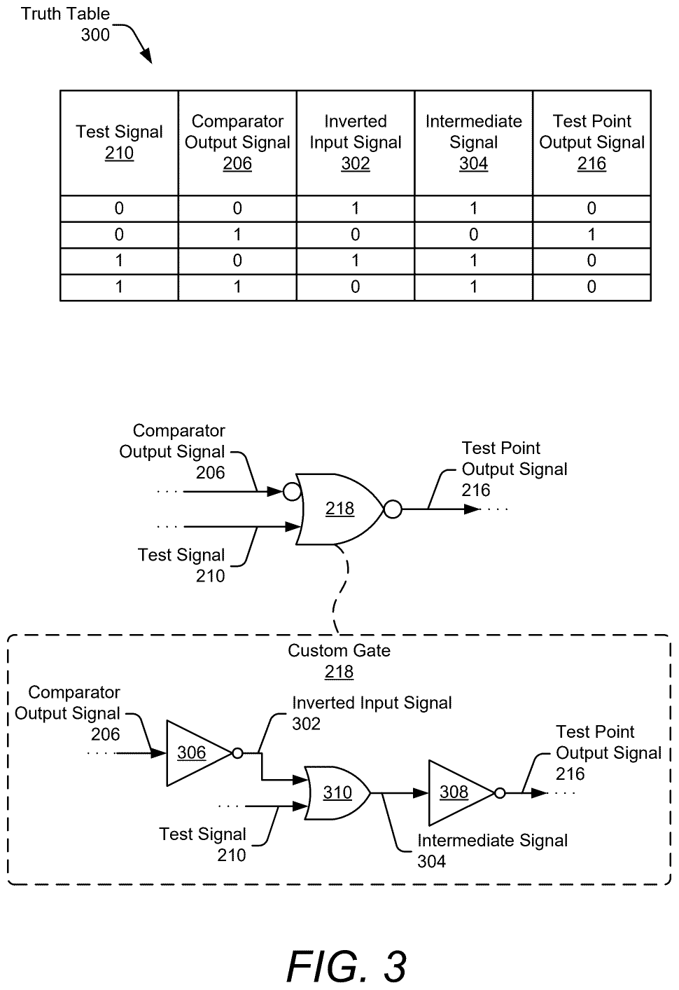

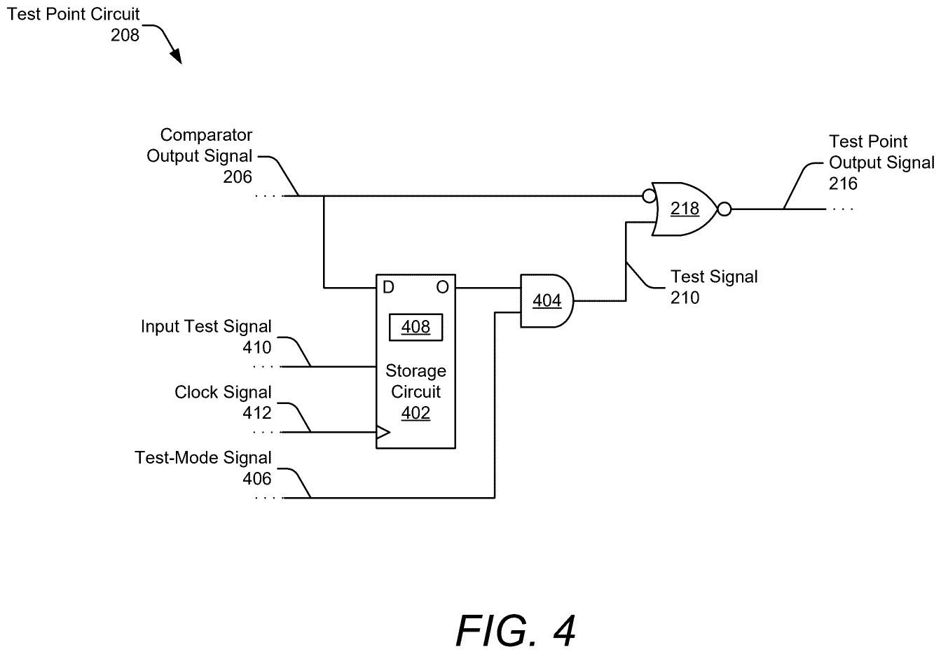

The device 102 also includes at least one test point circuit 208, which supports of testing of the comparator circuit 202. For testing purposes, the test point circuit 208 can control a signal that is provided to the comparator circuit 202 and observe a signal that is generated by the comparator circuit 202. To perform this testing, the test point circuit 208 uses a custom NOR-based design with an inverted input, which is further described below and in FIG. 3. Although not explicitly shown in FIG. 2, the test point circuit 208 can include other components such as a storage circuit and/or another logic gate, as shown in FIG. 4. In some implementations, one or more of the components within the test point circuit 208, such as the storage circuit, can also be implemented as part of a logic circuit, as further described with respect to FIG. 7.

During testing, the test point circuit 208 can accept the comparator output signal 206 at a first input, which represents an inverted input. The test point circuit 208 also accepts a test signal 210 at a second input, which represents a non-inverted input. The test signal 210 can indicate if testing is enabled (or disabled). In general, the generation of the test signal 210 and/or the data carried by the test signal 210 is at least dependent upon whether testing is enabled or disabled.

The test point circuit 208 performs an OR operation based on an inverted version of the comparator output signal 206 and the test signal 210. The test point circuit 208 inverts an output of this OR operation to generate a test point output signal 216. The test point output signal 216 can selectively represent the comparator output signal 206 during normal operations or a controlled test input signal during testing operations.

In a possible implementation, the test point circuit 208 includes at least one custom gate 218, such as a NOR gate with an inverted input representing the first input of the test point circuit 208 and a non-inverted input representing the second input of the test point circuit 208. The test point circuit 208 can be both part of normal operation as shown by the normal operation path 212 and testing operation of the device 102 as shown by the test operation path 214. This means that signals that are generated by the comparator circuit 202 pass through the test point circuit 208 (e.g., are operated on by the test point circuit 208) during normal operation and during testing. In other words, the test point circuit 208 is integrated within or forms part of the normal operation path 212 as well as the test operation path 214. The signals associated with the test point circuit 208 are further described with respect to FIG. 3.

FIG. 3 illustrates an example truth table 300 for the test point circuit 208. The signals associated with the truth table 300 include the test signal 210, the comparator output signal 206, an inverted input signal 302, an intermediate signal 304, and the test point output signal 216.

Consider the depicted functional representation of the custom gate 218 shown at the bottom of FIG. 3. In this case, the custom gate 218 performs the functions of (and can optionally be implemented using) at least two inverters 306 and 308 and at least one OR gate 310. The inverter 306 is coupled to the first input of the custom gate 218. The OR gate 310 has two inputs respectively coupled to an output of the inverter 306 and the second input of the custom gate 218. The inverter 308 is coupled between an output of the OR gate 310 and an output of the custom gate 218.

During operation of the test point circuit 208, the comparator output signal 206 is inverted (e.g., by the inverted input of the custom gate 218 or the inverter 306) to generate the inverted input signal 302. The intermediate signal 304 is generated (e.g., using the NOR-based design of the custom gate 218 or the OR gate 310) by performing an OR operation based on the inverted input signal 302 and the test signal 210. The test point output signal 216 is generated by inverting the intermediate signal 304 (e.g., using the NOR-based design of the custom gate 218 or the inverter 308).

As shown in the truth table 300, the test point output signal 216 is the same as the comparator output signal 206 if the test signal 210 is set to “0.” This means that the test point circuit 208 can be integrated within the normal operation path 212 such that it does not impact operation of the comparator circuit 202 during normal operations.

If the test signal 210 is set to a logic value of one, the test point output signal 216 is set to a logic value of zero. As a result, the test point output signal 216 is independent of the comparator output signal 206 if the test signal 210 is set to a logic value of 1. This provides the necessary control to facilitate testing of the comparator circuit 202. The test point circuit 208 can include other components to provide observability of the comparator output signal 206 for testing, as further described with respect to FIG. 4.

FIG. 4 illustrates an example test point circuit 208 for testing the comparator circuit 202. In some implementations, the test point circuit 208 includes at least one storage circuit 402 and at least one AND gate 404 along with the at least one custom gate 218. The AND gate 404 can have a first input coupled to an output of the storage circuit 402, a second input for receiving a test-mode signal 406, and an output coupled to a non-inverted input of the custom gate 218 (e.g., the second input of the custom gate 218). The AND gate 404 can generate the test signal 210, which is provided to the non-inverted input of the custom gate 218.

The storage circuit 402 can be implemented using a flop (e.g., a flip-flop), a latch, at least a portion of a register, multiple registers, and/or can be any other storage circuit. The storage circuit 402 can store data (e.g., information) associated with a signal. This stored data is represented by stored signal 408. In this example, the stored signal 408 can represent storage of the comparator output signal 206 or an input test signal 410. The stored signal 408 can be used to generate the test signal 210 when a test-mode signal 406 enables a test mode.

For example, during normal operation, the comparator output signal 206 can provide the stored signal 408, which provides for observability of the comparator output signal 206. The stored signal 408 is observed to analyze the comparator output signal 206 during testing of the device 102. During a scan-in operation, automatic test pattern generation can provide the input test signal 410 as the stored signal 408.

During testing, the AND gate 404 can provide a logic value of one when both the stored signal 408 and the test-mode signal 406 have logic values of one. This can provide for the controllability of the test point output signal 216. Other implementations of a test point that utilize an OR gate instead of the custom gate 218 would not be able to test a stuck-at-one fault because the comparator output signal 206 and an output of the storage circuit 402 would need to be zero, which is infeasible in many contexts, such as when testing a stuck-at-one fault from an output of an XOR tree to a clock enable input of a clock gate that provides a clock signal 412. Inversion of the comparator output signal 206 at the custom gate 218 allows a test point output signal 216 to have a logical value of one without requiring the comparator output signal 206 and the output of the storage circuit 402 to both have logical values of zero. Thus, controllability can be achieved for testing stuck-at-one and stuck-at-zero faults while allowing the comparator output signal 206 to have a logical value of one. Accordingly, test point output signal 216 control values of both one and zero can be obtained via the storage circuit 402.

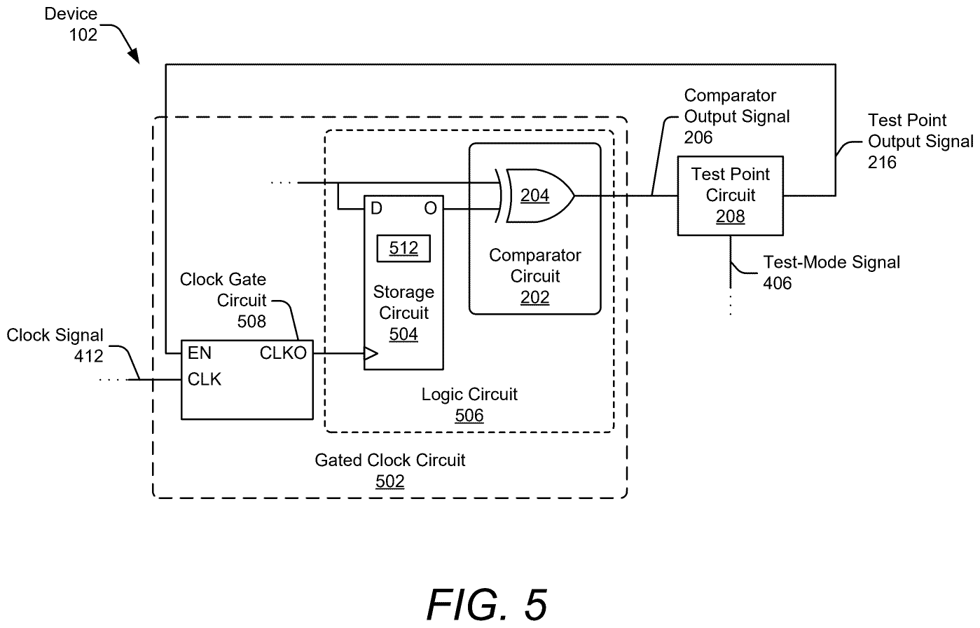

Although the above example faults focus on stuck-at-one and stuck-at-zero faults, the described techniques can also assist with testing other types of faults, including a transition delay fault, a cell-aware fault, and so forth. A relationship of the test point circuit 208 to other components within the device 102 are further described with respect to FIG. 5.

FIG. 5 illustrates an example relationship the test point circuit 208 and other components within the device 102. In the depicted example, the device 102 includes at least one gated clock circuit 502, which can disable the clock signal 412 (e.g., halt the propagation of the clock signal 412) to at least one storage circuit 504 to reduce dynamic power when data in the storage circuit 504 remains unchanged. The gated clock circuit 502 includes at least one logic circuit 506 and at least one clock gate circuit 508. The logic circuit 506 includes the storage circuit 504 and the comparator circuit 202. The storage circuit 504 can be implemented using a flop (e.g., a flip-flop), a latch, at least a portion of a register, and/or any other storage circuit.

A data input and an output of the storage circuit 504 are coupled to respective inputs of the XOR gate 204 of the comparator circuit 202. The clock gate circuit 508 receives the clock signal 412 at a clock input (CLK). The clock gate circuit 508 has an enable input (EN) coupled to an output of the comparator circuit 202 via the test point circuit 208. The clock gate circuit 508 can selectively be in an enabled state or a disabled state based on the enable input. If the enable input is set to a logical value of zero, the clock gate circuit 508 is in an enabled state that stops the clock signal 412 from propagating to the storage circuit 504. Alternatively, if the enable input is set to a logical value of one, the clock gate circuit 508 is in a disabled state, which propagates the clock signal 412 to the storage circuit 504 via an output of the clock gate circuit 508.

For example, during normal operation, the comparator circuit 202 sends the comparator output signal 206 via the test point circuit 208 to enable the clock gate circuit 508 via the enable input when a stored signal 512 is unchanged. For example, the XOR gate 204 of the comparator circuit 202 operates to enable the clock gate circuit 508 to stop the clock signal 412 from reaching the storage circuit 504 when data on the input and output of the storage circuit 504 is the same. When the clock gate circuit 508 is disabled, it outputs the clock signal 412 to a clock input of the storage circuit 504.

During testing operation, the test-mode signal 406 enables the test point circuit 208. The enabled test point circuit 208 can send a desired value as the test point output signal 216. In a possible implementation, the storage circuit 504 is a flip-flop. The comparator circuit 202 generates the comparator output signal 206 based on a comparison of a first signal at the data input (D) of the storage circuit 504 with a second signal at the output (O) of the storage circuit 504. The gated clock circuit 502 causes the clock gate circuit 508 to be in the enabled state and stop the propagation of the clock signal 412 based on the comparator output signal 206 indicating that the signal at the data input (D) is the same as the signal at the output (O) of the storage circuit 504. The signals provided at the data input and the output of the storage circuit 504 are considered to be the “same” if the data carried by these signals are the same. In other words, the similarity is with respect to the content of the data and not necessarily waveform characteristics of the signals (e.g., amplitude, frequency, or phase).

The test point circuit 208 can be used for controllability and observability of a signal provided to the enable input of the clock gate circuit 508. In particular, the test point circuit 208 can provide the test point output signal 216 as a control signal to provide a desired value to the enable input of the clock gate circuit 508 when the test-mode signal 406 initiates a test mode. The test point circuit 208 can also be used to observe the comparator output signal 206 during the operation of the device 102. Thus, the test point circuit 208 can be used for controllability and observability of a signal provided to the enable input of the clock gate circuit 508. Some implementations of the device 102 can include multiple logic circuits 506, as further described with respect to FIG. 6.

FIG. 6 is an example illustration of the device 102 including the test point circuit 208 and multiple logic circuits 506-1 to 506-N. The variable N represents a positive integer. Each logic circuit 506 includes at least one comparator circuit 202 and at least one storage circuit 504. The enable input of the clock gate circuit 508 is coupled to each comparator circuit 202 via the test point circuit 208. The output of the clock gate circuit 508 provides a gated clock signal 602 to the clock input of each storage circuit 504 of each logic circuit 506. An OR gate 604 is coupled between the test point circuit 208 and the multiple comparator circuits 202 of the logic circuits 506-1 to 506-N.

Each comparator circuit 202 of each logic circuit 506 can generate a respective comparator output signal 206 to generate a plurality of comparator output signals. The OR gate 604 can perform an OR operation based on the comparator output signals 206 to generate a composite signal 606, which is accepted by the test point circuit 208. In this implementation, the composite signal 606 represents the comparator output signal 206 of FIGS. 2-4.

The OR gate 604 and each comparator circuit 202 of each logic circuit 506 can form a shared comparator circuit 608 with a tree of XOR gates 204. This can allow XOR gating of the clock signal 412 to be shared across multiple storage circuits 504 of the logic circuits 506 by creating a combined enable condition with a tree of XOR gates 204 in the logic circuits 506. Sharing of the XOR gating can reduce area and power overhead by using one cock gate circuit 508 for multiple logic circuits 506.

A scan-enable signal 610 to a test-enable (TE) input of the clock gate circuit 508 can override the normal operation of the clock gate circuit 508 to ensure that the clock signal 412 can reach all parts of the device 102 for testing. For example, in normal operation, a signal at the enable input (EN) of the clock gate circuit 508 determines whether or not the clock signal 412 is gated. The scan-enable signal 610 can bypass the clock gate circuit 508 during testing to test all flip-flops, registers, sequential elements, and other elements in the device 102. The scan-enable signal 610 can ensure the clock signal 412 is not gated when testing is being conducted, regardless of the state of the enable input of the clock gate circuit 508.

As described above with respect to FIG. 5, the test point circuit 208 can be used for controllability and observability of a signal provided to the enable input of the clock gate circuit 508. In particular, the test point circuit 208 can provide the test point output signal 216 as a control signal to provide a desired value to the enable input of the clock gate circuit 508 when the test-mode signal 406 initiates a test mode.

In some instances, the test point circuit 208 can eliminate the requirement of controlling all the inputs and outputs of storage circuits 504 in the logic circuits 506 to have the same value to test a stuck-at-one fault at inputs and outputs of the comparator circuit 202 and at the enable input of the clock gate circuit 508. For example, the test point circuit 208 can provide a value of one without requiring the inputs (D) and outputs (O) of each storage circuit 504 in each logic circuit 506 to have equal values (D=O). This requirement is otherwise a challenge due to the need to generate a test vector to control many inputs and outputs, which is difficult in a compressed test environment scenario. This requirement also means the fault cannot otherwise be observed when testing a device with multiple logic circuits where false negative comparator faults are redundant and almost impossible to test. The test point circuit 208 allows for easier controllability and observability of the comparator output signals 206 and the signals at the enable input of the clock gate circuit 508 without requiring equal values on the inputs and outputs of storage circuits 504 in each logic circuit 506. In some implementations, at least a portion of the test point circuit 208 can be implemented using one of the logic circuits 506, as further described with respect to FIG. 7.

FIG. 7 is an example illustration of device 102 including the test point circuit 208, where elements common with the device 102 of FIG. 6 perform similar operations. While the device 102 of FIG. 6 has a test point circuit 208 that does not share components with any of the logic circuits 506-1 to 506-N, the device 102 of FIG. 7 includes a test point circuit 208 that shares a component with one of the logic circuits 506 to form a test and logic circuit 702. The test and logic circuit 702 includes the custom gate 218 and the AND gate 404, which are specific to implementing the test point circuit 208. Additionally, the test and logic circuit 702 includes the XOR gate 204, which is specific to implementing a logic circuit 506.

The test and logic circuit 702 also includes a storage circuit 504, which is a component that is used to implement both the test point circuit 208 and the logic circuit 506 in FIG. 7. Explained another way, the test and logic circuit 702 can reuse the storage circuit 504 of FIGS. 5 and 6 for the storage circuit 402 of FIG. 4. For example, within the test and logic circuit 702, a storage circuit 504 of a logic circuit 506 can be reused to provide the storage functionality of the test point circuit 208.

The test and logic 702 circuit can also include a multiplexor 706. The multiplexor 706 includes a first input that receives a comparator output signal 206, such as the composite signal 606 in this example. The multiplexor 706 also includes a second input configured to accept a scan-in signal 708, which can represent the input test signal 410 of FIG. 4. A control input of the multiplexor 706 accepts the scan-enable signal 610. The multiplexor 706 further includes an output coupled to a scan-in input of the storage circuit 504. In operation, the multiplexor 706 provides a multiplexor output signal 710 to the scan-in (SI) input of the storage circuit 704. The multiplexor output signal 710 can be based on one of: the composite signal 606 (e.g., the signal at the first input of the multiplexor 706) or the scan-in signal 708 (e.g., the signal at the second input of the multiplexor 706).

In a possible implementation, the clock gate circuit 508 receives the scan-enable signal 610 at the test-enable (TE) input. The multiplexor 706 also receives the scan-enable signal 610 at the control input. The multiplexor 706 sends the scan-in signal 708 to the scan-in input of the storage circuit 504 based on the scan-enable signal 610 representing a first value. Alternatively, the multiplexor 706 sends the composite signal 606 to the scan-in input based on the scan-enable signal 610 representing a second value that is different than the first value.

In an example implementation, the device 102 also includes an OR gate 712. The OR gate 712 includes a first input that receives the scan-enable signal 610, a second input that accepts the test-mode signal 406, and an output coupled to a scan-enable input of the storage circuit 504. The OR gate 712 provides for receiving the multiplexor output signal 710 at the scan-in input of the storage circuit 504 based on performing an OR operation on the scan-enable signal 610 and the test-mode signal 406.

The test and logic circuit 702 can provide a storage circuit 504 that serves the operation of a logic circuit 506 and serves the operation of the test point circuit 208. In effect, the storage circuit 504 is reused from an existing logic circuit 506 for use as a control and observe test point. Any storage circuit 504 can otherwise be used for the test point circuit 208. In the present implementation, one of the storage circuits 504 in one of the existing logic circuits 506 is reused for the test and logic circuit 702 to keep the proximity of the storage circuit 504 close to the other logic circuits 506. This allows for similar timing with the gated clock signal 602.

Observability of the storage circuit 504 during testing is enabled by a scan path through the scan-in input of the storage circuit 504. This can avoid extra overhead on the functional path through the data input (D), which can reduce timing issues that would otherwise be caused by non-correlation of functional and shift paths if scan-enable of the storage circuit 504 is attempted to observe faults.

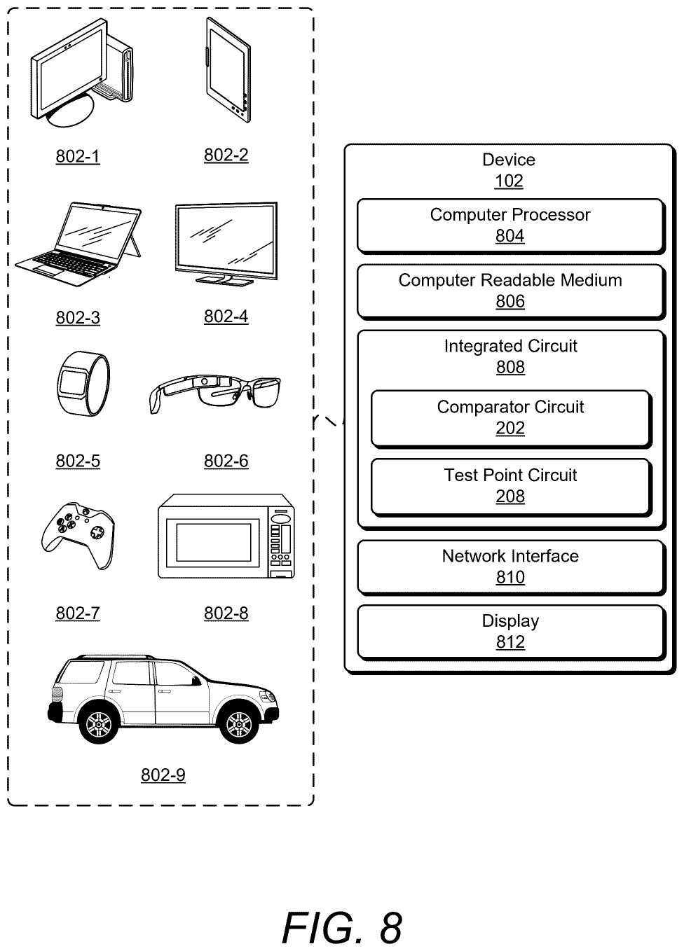

Reusing a storage circuit 504 of a logic circuit 506 for the test point circuit 208 can reduce the need for an extra storage circuit, which can significantly reduce the area requirements when integrating the test point circuit 208 within the device 102. It can also eliminate the need to share a dedicated test point circuit across all logic circuits 506. Implementation of the storage circuit 504 for the test point circuit 208 can be done at any stage of circuit synthesis, even late in place and route cycle with no dependency for scan insertion. For example, the storage circuit 504 can already be present as a functional register during a design-for-test insertion phase and it would have already been mapped to a scan register and connected to a scan chain. Example types of devices 102 are further described with respect to FIG. 8.

FIG. 8 illustrates an example device 102 (e.g., a computing device) capable of testing of a comparator circuit 202. The device 102 is illustrated with various non-limiting example devices including a desktop computer 802-1, a tablet 802-2, a laptop 802-3, a television 802-4, a computing watch 802-5, computing glasses 802-6, a gaming system 802-7, a microwave 802-8, and a vehicle 802-9. Other devices may also be used, such as a home service device, a smart speaker, a smart thermostat, a baby monitor, a Wi-Fi™ router, a drone, a trackpad, a drawing pad, a netbook, an e-reader, a home automation and control system, a wall display, and another home appliance. Note that the device 102 can be wearable, non-wearable but mobile, or relatively immobile (e.g., desktops and appliances).

The device 102 includes one or more computer processors 804 and at least one computer-readable medium 806, which includes memory media and storage media. Applications and/or an operating system (not shown) embodied as computer-readable instructions on the computer-readable medium 806 can be executed by the computer processor 804 to provide some of the functionalities described herein.

The device 102 can also include an integrated circuit 808. The integrated circuit 808 can include the comparator circuit 202 and the test point circuit 208. The device 102 can further include a network interface 810 for communicating data over wired, wireless, or optical networks. For example, the network interface 810 may communicate data over a local-area-network (LAN), a wireless local-area-network (WLAN), a personal-area-network (PAN), a wire-area-network (WAN), an intranet, the Internet, a peer-to-peer network, point-to-point network, a mesh network, Bluetooth®, and the like. The device 102 may optionally include a display 812.

### Example Method

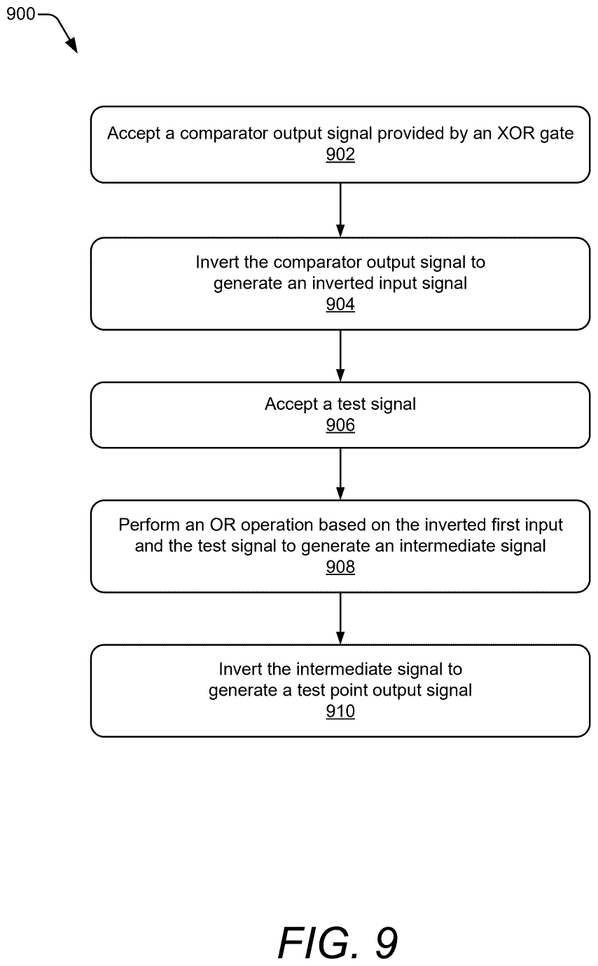

FIG. 9 depicts an example method 900 for testing a comparator circuit. Method 900 is shown as sets of operations (or acts) performed but not necessarily limited to the order or combinations in which the operations are shown herein. Further, any of one or more of the operations may be repeated, combined, reorganized, or linked to provide a wide array of additional and/or alternate methods. In portions of the following discussion, reference may be made to the environment 100 of FIG. 1, and entities detailed in FIGS. 2-7, reference to which is made for example only. Method 900 can be performed, at least partially, by the test point circuit 208, but techniques are not limited to performance by one entity or multiple entities operating on one device.

At 902 in FIG. 9, a comparator output signal provided by an XOR gate is accepted. For example, the test point circuit 208 accepts the comparator output signal 206. In some cases, accepting of the comparator output signal 206 includes accepting the comparator output signal 206 at an inverted input of the custom gate 218 of the test point circuit 208. The test point output signal 216 can be provided to an enable input of a clock gate circuit 508. Based on the test point output signal 216, a gated clock signal 602 can be provided from an output of the clock gate circuit 508 to a clock input of a storage circuit 504.

The comparator output signal 206 can be generated by performing an XOR operation on the signal 512 stored by the storage circuit 504 and an input signal provided at a data input of the storage circuit 504, as shown in FIG. 5. In one aspect, storing the signal 512 includes storing the signal as stored data in a flip-flop. Passing of a clock signal 412 from the clock gate circuit 508 to the storage circuit 504 can be disabled based on the stored data remaining unchanged.

In other cases, a plurality of the comparator output signals 206 is generated by a plurality of logic circuits 506-1 through 506-N, as shown in FIG. 6. A composite signal 606 is generated by the OR gate 604 based on the plurality of the comparator output signals 206. In these cases, the accepting of the comparator output signal provided by the XOR gate includes accepting the composite signal 606.

At 904, the comparator output signal is inverted to generate an inverted input signal. For example, the test point circuit 208 inverts the comparator output signal 206 to generate an inverted input signal 302. In one aspect, an inverted input of the custom gate 218 inverts the comparator output signal 206. In another aspect, an inverter 306 can be used to implement a portion of the custom gate 218. This inverter 306 inverts the comparator output signal 206 to generate the inverted input signal 302, as shown in FIG. 3.

At 906, a test signal is accepted. For example, the test point circuit 208 accepts the test signal 210, as shown in FIG. 2. In one aspect, a non-inverted input of the custom gate 218 accepts the test signal 210. In another aspect, the test signal 210 is accepted at an OR gate 310, which is used to implement a portion of the custom gate 218, as shown in FIG. 3. Information within the test signal 210 is based, at least in part, on whether testing is enabled or disabled.

In some cases, a stored signal 408 is generated based on the comparator output signal 206 or the test signal 210. A test-mode signal 406 is received and an AND operation can be performed on the stored signal 408 and the test-mode signal 406 to generate the test signal 210, as shown in FIG. 4.

At 908, an OR operation is performed based on the inverted first input and the test signal to generate an intermediate signal. For example, the test point circuit 208 performs an OR operation based on the inverted input signal 302 and the test signal 210 to generate an intermediate signal 304. In one aspect, the NOR-based design of the custom gate 218 performs the OR operation. In another aspect, an OR gate 310 can perform this operation. In this case, the OR gate 310 implements a portion of the custom gate 218.

At 910, the intermediate signal is inverted to generate a test point output signal. For example, the test point circuit 208 inverts the intermediate signal 304 to generate the test point output signal 216. In one aspect, the NOR-based design of the custom gate 218 performs this inversion operation to generate the test point output signal 216. In another aspect, an inverter 308 can be used to implement a portion of the custom gate 218. This inverter 308 inverts the intermediate signal 304 to generate the test point output signal 216, as shown in FIG. 3.

Although not explicitly shown in FIG. 9, some implementations for testing a comparator circuit can use the multiplexor 706 to generate a multiplexor output signal 710 based on one of: the comparator output signal 206 or a scan-in signal 708. The multiplexor output signal 710 is provided to a scan-in input of the storage circuit 504. In one aspect, the storage circuit 504 receives a scan-enable signal. Providing the multiplexor output signal 710 includes sending the scan-in signal 708 to the scan-in input based on the scan-enable signal representing a first value and sending the comparator output signal 206 to the scan-in input based on the scan-enable signal representing a second value that is different than the first value. In one aspect, an OR operation is performed on the scan-enable signal and a test-mode signal 406. For example, the OR gate 712 performs the OR operation. The multiplexor output signal 710 is received at the scan-in input of the storage circuit 504 based on performing the OR operation.

### CONCLUSION

Although techniques using, and apparatuses including, testing a comparator circuit have been described in language specific to features and/or methods, it is to be understood that the subject of the appended claims is not necessarily limited to the specific features or methods described. Rather, the specific features and methods are disclosed as example implementations of testing a comparator circuit.

Some Examples are described below.

Example 1: An apparatus comprising:
a comparator circuit comprising:
   an XOR gate,
   the comparator circuit configured to generate a comparator output signal using the XOR gate; and
a test point circuit configured to:
   accept the comparator output signal at a first input of the test point circuit;
   invert the comparator output signal to generate an inverted input signal;
   accept a test signal at a second input of the test point circuit;
   perform an OR operation based on the inverted input signal and the test signal to generate an intermediate signal; and
   invert the intermediate signal to generate a test point output signal.

Example 2: The apparatus according to example 1, wherein the test point circuit comprises a NOR gate comprising:
an inverted input representing the first input of the test point circuit; and
a non-inverted input representing the second input of the test point circuit.

Example 3: The apparatus according to example 2, wherein the test point circuit further comprises:
a first storage circuit; and
an AND gate having:
   a first input coupled to an output of the first storage circuit;
   a second input configured to receive a test-mode signal; and
   an output coupled to the second input of the NOR gate.

Example 4: The apparatus according any previous example, further comprising a gated clock circuit, the gated clock circuit comprising:
the comparator circuit;
a second storage circuit having:
   an input and an output coupled to respective inputs of the XOR gate; and
   a clock input; and
a clock gate circuit having:
   an enable input coupled to the comparator circuit output via the test point circuit; and
   a clock output coupled to the clock input of the storage circuit.

Example 5: The apparatus according to example 4, wherein:
the second storage circuit comprises a flip-flop;
the clock gate circuit is configured to selectively be in:
   a disabled state that passes a clock signal from a clock input of the clock gate circuit to the clock output; or
   an enabled state that prevents propagation of the clock signal from the clock input of the clock gate circuit to the clock output;
the comparator circuit is configured to generate the comparator output signal based on a comparison of a first signal at an input of the flip-flop with a second signal at an output of the flip-flop; and
the gated clock circuit is configured to cause the clock gate circuit to be in the enabled state based on the comparator output signal indicating that the first signal is the same as the second signal.

Example 6: The apparatus according to example 4 or 5, further comprising a plurality of logic circuits, each comprising at least one of the comparator circuit and at least one of the second storage circuit,
wherein the enable input of the clock gate circuit is coupled to each of the comparator circuits via the test point circuit and the clock output is coupled to the clock input of each storage circuit.

Example 7: The apparatus according to any one of examples 4-6, wherein:
the second storage circuit comprises a scan-in input; and
the apparatus further comprises a multiplexor comprising:
   a first input that receives the comparator output signal;
   a second input configured to accept a scan-in signal; and
   an output coupled to the scan-in input.

Example 8: The apparatus according to example 7, wherein
the clock gate circuit receives a scan-enable signal at a test-enable input; and the multiplexor is configured to:
   receive the scan-enable signal at a control input of the multiplexor;
   send the scan-in signal to the scan-in input based on the scan-enable signal representing a first value; and
   send a signal from the comparator circuit output to the scan-in input based on the scan-enable signal representing a second value that is different than the first value.

Example 9: The apparatus according to example 8, further comprising an OR gate, the OR gate comprising:
a first input that receives the scan-enable signal;
a second input that accepts a test-mode signal; and
an output coupled to a scan-enable input of the second storage circuit.

Example 10: The apparatus according to any previous example, wherein the test point circuit is configured to test a stuck-at-one fault corresponding to an input of the comparator circuit.

Example 11: A method performed by a test point circuit, the method comprising:
accepting a comparator output signal provided by an XOR gate;
inverting the comparator output signal to generate an inverted first input;
accepting a test signal;
performing an OR operation based on the inverted first input and the test signal to generate an intermediate signal; and
inverting the intermediate signal to generate a test point output signal.

Example 12: The method according to example 10, wherein:
the accepting of the comparator output signal at the first input comprises accepting the comparator output signal at an inverted input of a NOR gate of the test point circuit; and
the accepting of the test signal comprises accepting the test signal at a non-inverted input of the NOR gate.

Example 13: The method according to example 11 or 12, further comprising:
generating a stored signal based on the comparator output signal;
receiving a test-mode signal; and
performing an AND operation on the stored signal and the test-mode signal to generate the test signal.

Example 14: The method according to any one of examples 11-13, further comprising:
storing a signal in a storage circuit;
generating the comparator output signal by performing an XOR operation on a signal stored by the storage circuit and an input signal to the storage circuit;
providing the test point output signal to an enable input of a clock gate circuit; and
providing, based on the test point output signal, a gated clock signal from an output of the clock gate circuit to a clock input of the storage circuit.

Example 15: The method according to example 14, further comprising:
disabling passing of a clock signal from the clock gate circuit to the storage circuit based on data in the storage circuit remaining unchanged,
wherein storing the signal comprises storing the signal in a flip-flop.

Example 16: The method according to example 14 or 15, further comprising:
generating a plurality of comparator output signals;
performing another OR operation based on the plurality of comparator output signals; and
generating a composite signal based on the another OR operation,
wherein the accepting of the comparator output signal provided by the XOR gate comprises accepting the composite signal.

Example 17: The method according to any one of examples 14-16, further comprising:
generating a multiplexor output signal based on one of: the comparator output signal or a scan-in signal; and
providing the multiplexor output signal to a scan-in input of the storage circuit.

Example 18: The method according to example 17, further comprising:
receiving a scan-enable signal,
wherein providing the multiplexor output signal comprises:
   sending the scan-in signal to the scan-in input based on the scan-enable signal representing a first value; and
   sending the comparator output signal to the scan-in input based on the scan-enable signal representing a second value that is different than the first value.

Example 19: The method according to example 18, further comprising:
performing an OR operation on the scan-enable signal and a test-mode signal; and
receiving the multiplexor output signal at the scan-in input based on performing the OR operation.

Example 20: The method according to any one of examples 11-19, further comprising:
testing a stuck-at-one fault corresponding to an input a comparator circuit comprising the XOR gate.

What is claimed is:

1. An apparatus comprising:
a comparator circuit comprising:
an XOR gate,
the comparator circuit configured to generate a comparator output signal using the XOR gate; and
a test point circuit configured to:
accept the comparator output signal at a first input of the test point circuit;
invert the comparator output signal to generate an inverted input signal;
accept a test signal at a second input of the test point circuit;
perform an OR operation based on the inverted input signal and the test signal to generate an intermediate signal; and
invert the intermediate signal to generate a test point output signal.

2. The apparatus according to claim 1, wherein the test point circuit comprises a NOR gate comprising:
an inverted input representing the first input of the test point circuit; and
a non-inverted input representing the second input of the test point circuit.

3. The apparatus according to claim 2, wherein the test point circuit further comprises:
a first storage circuit; and
an AND gate having:
a first input coupled to an output of the first storage circuit;
a second input configured to receive a test-mode signal; and
an output coupled to the second input of the NOR gate.

4. The apparatus according claim 1, further comprising a gated clock circuit, the gated clock circuit comprising:
the comparator circuit;
a second storage circuit having:
an input and an output coupled to respective inputs of the XOR gate; and
a clock input; and
a clock gate circuit having:
an enable input coupled to the comparator circuit output via the test point circuit; and
a clock output coupled to the clock input of the storage circuit.

5. The apparatus according to claim 4, wherein:
the second storage circuit comprises a flip-flop;
the clock gate circuit is configured to selectively be in:
a disabled state that passes a clock signal from a clock input of the clock gate circuit to the clock output; or
an enabled state that prevents propagation of the clock signal from the clock input of the clock gate circuit to the clock output;
the comparator circuit is configured to generate the comparator output signal based on a comparison of a first signal at an input of the flip-flop with a second signal at an output of the flip-flop; and
the gated clock circuit is configured to cause the clock gate circuit to be in the enabled state based on the comparator output signal indicating that the first signal is the same as the second signal.

6. The apparatus according to claim 4, further comprising a plurality of logic circuits, each comprising at least one of the comparator circuit and at least one of the second storage circuit,
wherein the enable input of the clock gate circuit is coupled to each of the comparator circuits via the test point circuit and the clock output is coupled to the clock input of each storage circuit.

7. The apparatus according to claim 4, wherein:
the second storage circuit comprises a scan-in input; and
the apparatus further comprises a multiplexor comprising:
a first input that receives the comparator output signal;
a second input configured to accept a scan-in signal; and
an output coupled to the scan-in input.

8. The apparatus according to claim 7, wherein
the clock gate circuit receives a scan-enable signal at a test-enable input; and
the multiplexor is configured to:
receive the scan-enable signal at a control input of the multiplexor;
send the scan-in signal to the scan-in input based on the scan-enable signal representing a first value; and
send a signal from the comparator circuit output to the scan-in input based on the scan-enable signal representing a second value that is different than the first value.

9. The apparatus according to claim 8, further comprising an OR gate, the OR gate comprising:
a first input that receives the scan-enable signal;
a second input that accepts a test-mode signal; and
an output coupled to a scan-enable input of the second storage circuit.

10. The apparatus according to claim 1, wherein the test point circuit is configured to test a stuck-at-one fault corresponding to an input of the comparator circuit.

11. A method performed by a test point circuit, the method comprising:
accepting a comparator output signal provided by an XOR gate;
inverting the comparator output signal to generate an inverted first input;
accepting a test signal;
performing an OR operation based on the inverted first input and the test signal to generate an intermediate signal; and
inverting the intermediate signal to generate a test point output signal.

12. The method according to claim 11, wherein:
the accepting of the comparator output signal at the first input comprises accepting the comparator output signal at an inverted input of a NOR gate of the test point circuit; and
the accepting of the test signal comprises accepting the test signal at a non-inverted input of the NOR gate.

13. The method according to claim 11, further comprising:
generating a stored signal based on the comparator output signal;
receiving a test-mode signal; and
performing an AND operation on the stored signal and the test-mode signal to generate the test signal.

14. The method according to claim 11, further comprising:
storing a signal in a storage circuit;
generating the comparator output signal by performing an XOR operation on a signal stored by the storage circuit and an input signal to the storage circuit;
providing the test point output signal to an enable input of a clock gate circuit; and
providing, based on the test point output signal, a gated clock signal from an output of the clock gate circuit to a clock input of the storage circuit.

15. The method according to claim 14, further comprising:
disabling passing of a clock signal from the clock gate circuit to the storage circuit based on data in the storage circuit remaining unchanged,
wherein storing the signal comprises storing the signal in a flip-flop.

16. The method according to claim 14, further comprising:
generating a plurality of comparator output signals;
performing another OR operation based on the plurality of comparator output signals; and
generating a composite signal based on the another OR operation,
wherein the accepting of the comparator output signal provided by the XOR gate comprises accepting the composite signal.

17. The method according to claim 14, further comprising:
generating a multiplexor output signal based on one of: the comparator output signal or a scan-in signal; and
providing the multiplexor output signal to a scan-in input of the storage circuit.

18. The method according to claim 17, further comprising:
receiving a scan-enable signal,
wherein providing the multiplexor output signal comprises:
sending the scan-in signal to the scan-in input based on the scan-enable signal representing a first value; and
sending the comparator output signal to the scan-in input based on the scan-enable signal representing a second value that is different than the first value.

19. The method according to claim 18, further comprising:
performing an OR operation on the scan-enable signal and a test-mode signal; and
receiving the multiplexor output signal at the scan-in input based on performing the OR operation.

20. The method according to claim 11, further comprising:
testing a stuck-at-one fault corresponding to an input of a comparator circuit comprising the XOR gate.
